(19) United States
(12) Patent Application Publication
(10) Pub. No.: US 2026/0239703 A1
(43) Pub. Date: Aug. 13, 2026

(54) SEMICONDUCTOR DEVICE AND METHOD FOR FABRICATING THE SAME

(71) Applicant: Hon Young Semiconductor Corporation, Hsinchu City (TW)

(72) Inventors: Yen Cheng HUANG, Hsinchu City (TW); Kuang-Hao CHIANG, Hsinchu City (TW); Jing-Neng YAO, Hsinchu City (TW)

(21) Appl. No.: 19/075,768

(22) Filed: Mar. 10, 2025

(30) Foreign Application Priority Data
Feb. 7, 2025 (TW) 114104500

(51) Int. Cl. H01L 21/28; H10D 30/66; H10D 64/01; H10D 64/27; H10D 64/68

(52) U.S. Cl. CPC H10D 64/01348; H10D 64/027; H10D 64/513; H10D 64/516; H10D 64/693; H10D 30/668

(57) ABSTRACT

A method of fabricating a semiconductor device, including: forming a trench in a substrate; forming a barrier layer on a sidewall of the trench, in which the trench exposes an upper surface of the substrate; via the trench, performing an etching back process on the substrate to lower the upper surface of the substrate and exposing a side surface of the substrate; modifying an oxidation characteristic of the exposed upper surface and the side surface of the substrate; depositing a dielectric layer on the upper surface and the side surface of the substrate; and forming a gate structure on the dielectric layer.

### CROSS-REFERENCE TO RELATED APPLICATION

This application claims priority to Taiwan Application Serial Number 114104500, filed Feb. 7, 2025, which is herein incorporated by reference in its entirety.

### BACKGROUND

In order to reduce pitch and achieve lower R_{on,sp,} metal oxide semiconductor field effect transistors (MOSFETs) have evolved from planar to trench architecture. Currently, in SiC Trench MOSFETs, the corner area is often affected by high electric fields, this is due to the phenomenon of electric field concentration. This concentrated electric field usually occurs at the sharp corners between the gate and the source or drain, especially at the edge of the trench structure. Specifically, these high electric fields at the corners can have a negative impact on the gate oxide layer, leading to degradation or breakdown of the gate oxide layer, increase of the leakage current, decrease in the component breakdown voltage or a problem that the switch switching function fails. As the leakage current increases, the switching efficiency of the MOSFET will decrease, and may cause problems such as thermal runaway and shortened life, thus affecting the performance and stability of the overall circuit.

Therefore, a semiconductor device and method (such as improving the corner structure by corner rounding to reduce the electric field concentration phenomenon) are needed to solve the above problems.

### SUMMARY

The disclosure provides a method of fabricating a semiconductor device that includes forming a trench in a substrate; forming a barrier layer on a sidewall of the trench, in which the trench exposes an upper surface of the substrate; via the trench, performing an etching back process on the substrate to lower the upper surface of the substrate and exposing a side surface of the substrate; modifying an oxidation characteristic of the exposed upper surface and the side surface of the substrate; depositing a dielectric layer on the upper surface and the side surface of the substrate; and forming a gate structure on the dielectric layer.

In some embodiments, in which modifying the oxidation characteristic of the exposed upper surface and the side surface of the substrate comprises implanting a doping species into the substrate.

In some embodiments, in which the doping species is a P-type dopant, nitrogen (N) or argon (Ar).

In some embodiments, in which the doping species is implanted into the substrate at an inclined angle.

In some embodiments, further comprises removing the barrier layer before depositing the dielectric layer.

In some embodiments, in which forming the barrier layer comprises: forming a barrier layer material along the trench; and removing a portion of the barrier layer material located above the upper surface of the substrate.

The disclosure provides a semiconductor device that includes a substrate; a gate dielectric layer located in the substrate and has a horizontal portion along an upper surface of the substrate and a vertical portion along a side wall of the substrate, wherein the horizontal portion and the vertical portion intersect at a corner portion, wherein a dopant concentration of the corner portion is higher than a dopant concentration of the horizontal portion; and a gate structure located on the gate dielectric layer.

In some embodiments, in which a thickness of the corner portion is greater than a thickness of the horizontal portion and a thickness of the vertical portion.

In some embodiments, in which the thickness of the horizontal portion is greater than the thickness of the vertical portion.

In some embodiments, in which the horizontal portion and the corner portion have a dopant, wherein the dopant is a P-type dopant, nitrogen (N) or argon (Ar).

These and other features, aspects, and advantages of the present disclosure will become better understood with reference to the following description and appended claims.

It is to be understood that both the foregoing general description and the following detailed description are by examples, and are intended to provide further explanation of the disclosure as claimed.

### BRIEF DESCRIPTION OF THE DRAWINGS

The disclosure can be more fully understood by reading the following detailed description of the embodiment, with reference made to the accompanying drawings as follows:

FIGS. 1 to 7 are cross-sectional views of different steps of a method of fabricating a semiconductor device, in accordance with some embodiments of the present disclosure.

### DETAILED DESCRIPTION

Hereinafter, example embodiments will be explained in detail with reference to the accompanying drawings.

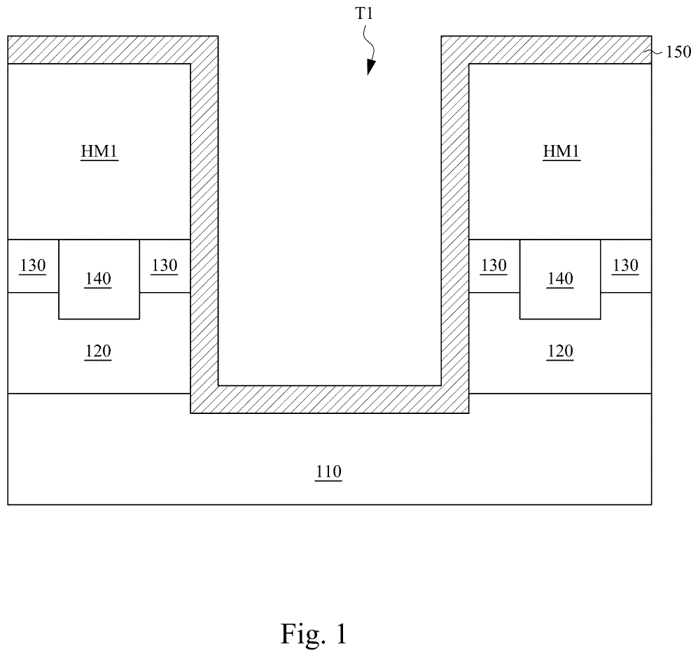

FIGS. 1 to 7 are cross-sectional views of different steps of a method of fabricating a semiconductor device, in accordance with some embodiments of the present disclosure. The method of FIGS. 1 to 7 is used to form a semiconductor device. Various operations of embodiments are provided herein. The order in which some or all of the operations are described should not be construed to imply that these operations are necessarily order dependent. Alternative ordering will be appreciated having the benefit of this description. Further, it will be understood that not all operations are necessarily present in each embodiment provided herein. Also, it will be understood that not all operations are necessary in some embodiments.

Referring to FIG. 1, In some embodiments, the initial structure includes a substrate 110, a well region 120, a first doped region 130, a second doped region 140, a hard mask layer HM1, and a barrier layer material 150. In some embodiments, the first doped region 130 may also be referred to as a source doped region.

First, a well region 120 and a first doped region 130 are formed on the substrate 110. In some embodiments, the substrate 110 may be made of a semiconductor material, such as silicon, silicon carbide, the like, or a combination thereof. In some embodiments, a thermal oxidation process may be performed on the substrate 110 to form a silicon oxide layer on the surface of the substrate 110. Then, an ion implantation process may be performed on the substrate 110 to implant ions into the substrate 110 to form the well region 120. In some embodiments, the well region 120 may include first type dopants. For example, the well region 120 may include P-type dopants, such as boron, aluminum, and gallium.

Next, a first doped region 130 is formed on the well region 120. In some embodiments, an ion implantation process may be performed to implant ions into the well region 120 to form the first doped region 130. In some embodiments, the first doped region 130 may include a second type dopant that is different from the first type dopant of the well region 120. In some embodiments, the first doped region 130 may include N-type dopants, such as nitrogen, arsenic, or phosphorus. In some embodiments, the first doped region 130 may also be referred to as a source/drain region.

Finally, a second doped region 140 is formed in the first doped region 130 and the well region 120. In some embodiments, a first patterned photoresist layer may be formed on the first doped region 130, and an ion implantation process may be performed to implant ions into the first doped region 130 and the well region 120 to form a second doped region 140. In some embodiments, the second doped region 140 may include dopants different from those of the first doped region 130. In some embodiments, the second doped region 140 may include a P-type dopant, such as boron, aluminum, or gallium. In some embodiments, the second doped region 140 penetrates the first doped region 130 and is located in the well region 120. The position of the second doped region 140 is defined by the first patterned photoresist layer. Next, the first patterned photoresist layer is removed.

A trench T1 is formed in the first doped region 130, the well region 120 and the substrate 110. Specifically, a hard mask layer HM1 may be formed on the first doped region 130 and the second doped region 140. In some embodiments, the hard mask layer HM1 may be formed of a dielectric material, such as silicon nitride, silicon oxide, the like, or a combination thereof. Next, the hard mask layer HM1 is used as an etching mask to form a trench T1 in the first doped region 130, the well region 120 and the substrate 110. The trench T1 may be formed by a dry etching process. The trench T1 has vertical sidewalls (e.g., sidewalls substantially perpendicular to the bottom of the substrate 110), the bottom of the trench T1 exposes the substrate 110, and the sidewalls of the trench T1 expose the hard mask layer HM1, the first doped region 130, the well region 120 and a portion of the substrate 110.

Next, a barrier layer material 150 is formed in the trench T1. Furthermore, the barrier layer material 150 may be formed by deposition. In some embodiments, the barrier layer material 150 covers the surface of the trench T1, which covers the upper surface of the substrate 110, the side surface of the well region 120, the side surface of the first doped region 130, and the side surface and upper surface of the hard mask layer HM1. In some embodiments, the barrier layer material 150 may be formed of a dielectric material, such as silicon nitride, silicon oxide, the like, or a combination thereof. The above description summarizes the initial structure 50. However, in some embodiments, not all of the structures in the initial structure 50 are necessary.

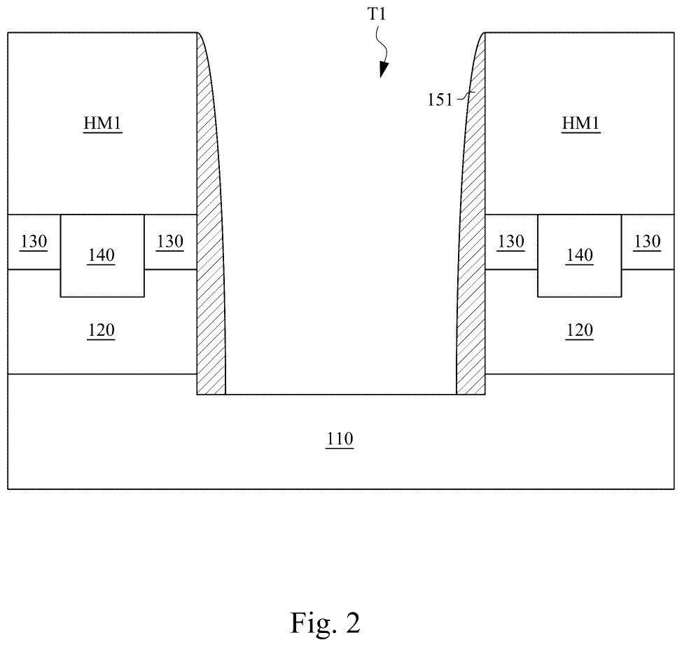

Referring to FIG. 2, horizontal portions of barrier layer material 150 may be selectively removed to form barrier layer 151. Generally speaking, according to the etching rate of the anisotropic etching process, the barrier layer material 150 at the bottom of the trench T1 and above the hard mask layer HM1 shown in this embodiment will be etched along with the anisotropic etching step, and is etched away to form a barrier layer 151 as shown in FIG. 2, which covers the sidewalls of the trench T1. In some embodiments, the formation of barrier layer 151 exposes a portion of the upper surface of substrate 110.

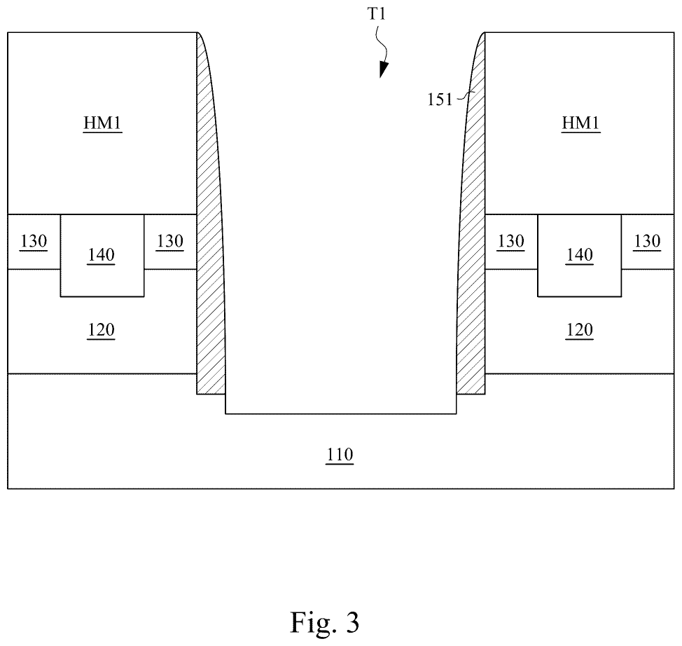

Referring to FIG. 3, the height of the upper surface of the substrate 110 can be further lowered by etching back to expose a portion of the side surface of the substrate 110. In some embodiments, the height of the exposed upper surface of the substrate 110 is lower than the height of the lower surface of the barrier layer 151. In some embodiments, the exposed side surface of the substrate 110 is leveled with the interface between the barrier layer 151 and the trench T1.

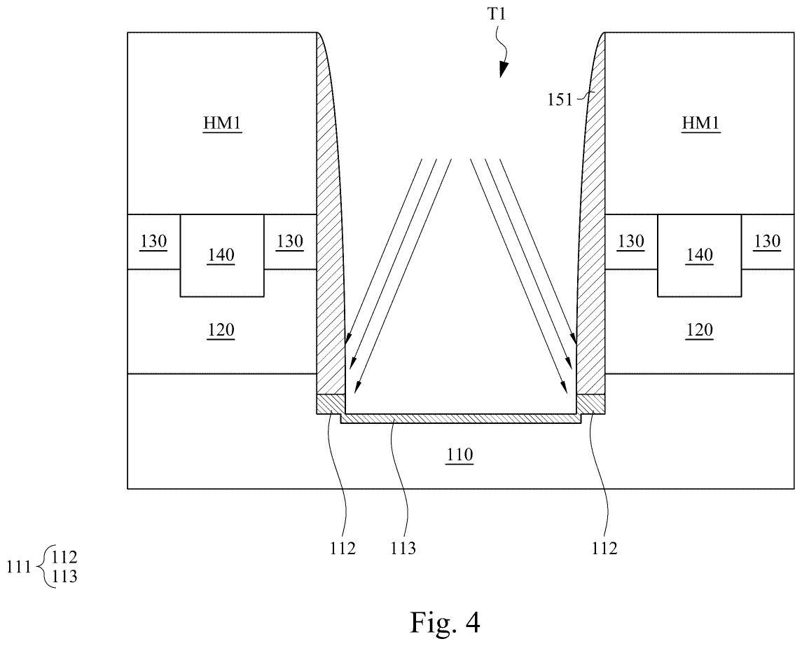

Referring to FIG. 4, an implantation process is performed on the substrate 110 exposed to the trench T1. In some embodiments, dopant species may be implanted into the side surface of the substrate 110 that is not covered by the barrier layer 151. Specifically, the implantation process implants dopant species into the portion of the substrate 110 directly below the barrier layer 151. In some embodiments, doping species may be implanted into the side surface of the substrate 110 at an oblique angle. For example, the incident direction of the doping species may have an angle greater than zero with respect to the normal line of the substrate 110, the doping species are injected therein, and then the substrate 110 is flipped 180° in the horizontal direction to direct the other side of the substrate 110 to the substrate 110. The doping species are implanted into the side surfaces, thereby implanting the doping species into the two side surfaces of the substrate 110 at the same angle. In some embodiments, some doping species are also implanted into the upper surface of the substrate 110. In some embodiments, the barrier layer 151 is configured to block doping species from being implanted into the well region 120, the first doped region 130, or the second doped region 140. In some embodiments, the implantation process forms a modified layer 111 on the exposed surface of the substrate 110.

In some embodiments, implanting dopant species into substrate 110 is performed using a dopant species amount in the range of approximately 1×10¹⁴ (ions/cm²). In some embodiments, the doping species implanted into the side surface of the substrate 110 is a doping species that can increase the oxidation rate of the region. In some embodiments, the doping species implanted into the side surface of the substrate 110 are ions that are more likely to form an amorphous state with respect to the material of the substrate 110, such as silicon carbide. In some embodiments, the doping species implanted into the side surface of the substrate 110 may include P-type dopants (eg, boron, aluminum, gallium). In other embodiments, the doping species may also include nitrogen (N) and/or argon (Ar) ions. In some embodiments, the doping species concentration of the modification layer 111 may be greater than the doping species concentration of the substrate 110. In some embodiments, the modified layer 111 has a higher concentration of P-type dopants, nitrogen and/or argon doping species than the substrate 110.

In some embodiments, the implantation process is configured to modify an oxidation characteristic of a top surface or a side surface of the substrate 110. In some embodiments, the modified layer 111 is configured to increase the oxidation rate of the region. In some embodiments, the modified layer 111 includes a corner portion 112 and a surface portion 113. Here, the corner portion 112 may be considered as a portion of the modification layer 111 directly below the barrier layer 151. In some embodiments, a thickness of the corner portion 112 is greater than a thickness of the surface portion 113. In some embodiments, the doping species concentration of the corner portion 112 may be greater than the doping species concentration of the surface portion 113. That is, the two ends of the modified layer 111 have a higher concentration of doping species, and the concentration of doping species in the modified layer 111 gradually decreases toward the center. In some embodiments, the corner portion 112 has a higher concentration of P-type dopants, nitrogen and/or argon than the surface portion 113. In some embodiments, the corner portion 112 and/or the surface portion 113 has a higher doping species concentration than that of the substrate 110. In some embodiments, the corner portion 112 and/or the surface portion 113 have a higher concentration of P-type dopants, nitrogen and/or argon than the substrate 110.

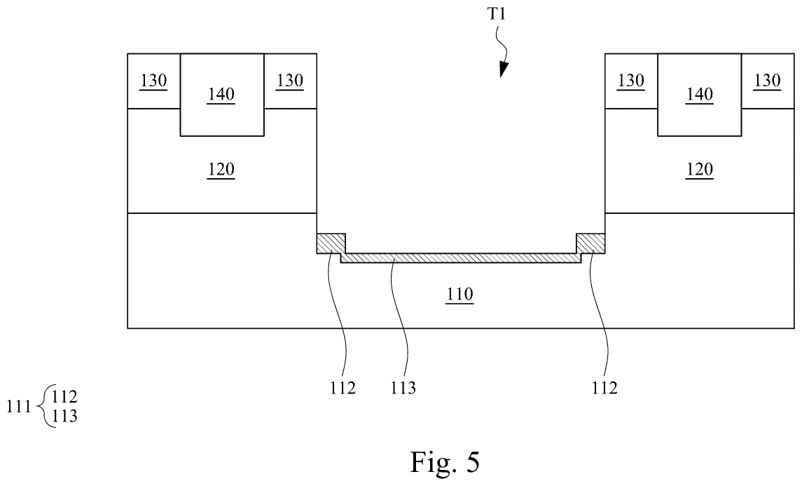

Referring to FIG. 5, an etching process may be used to remove the barrier layer 151 and the hard mask layer HM1 to expose the modified layer 111. In some embodiments, the barrier layer 151 and the hard mask layer HM1 are removed to expose the sidewalls of the substrate 110, the sidewalls of the well region 120, the sidewalls and the upper surface of the first doped region 130, and the upper surface of the second doped region 140. In some embodiments, the etching process may be wet etching, dry etching, or a combination thereof.

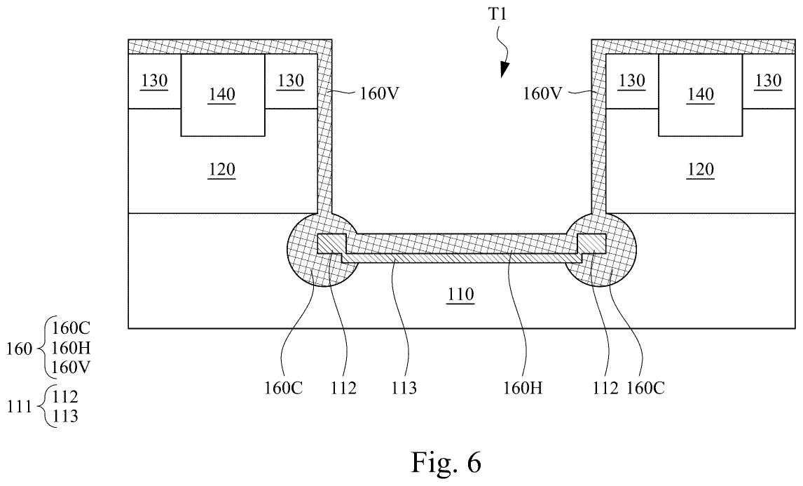

Referring to FIG. 6, a dielectric layer 160 may be deposited on the exposed surface of the substrate 110. In some embodiments, the dielectric layer 160 covers the upper surface of the modified layer 111, the sidewalls of the trench T1, and the upper surfaces of the first doped region 130 and the second doped region 140. In some embodiments, the dielectric layer 160 includes a dielectric material, such as silicon oxide, silicon nitride, the like, or a combination thereof. In some embodiments, the dielectric layer 160 may be used as a gate dielectric layer and configured to electrically isolate the gate from other conductive materials, such as the substrate 110, the well region 120 and/or the first The doped region 130. In some embodiments, the dielectric layer 160 has a dome-shaped structure.

In the embodiment where the dielectric layer 160 is an oxide layer, the dielectric layer 160 can be formed by oxidizing the exposed surface of the substrate 110. As mentioned above, because the modified layer 111 increases the oxidation rate of the region, the region near the modified layer 111 has a thicker oxide layer than the remaining region. For example, the thickness of the dielectric layer 160 located in the modification layer 111 (including the surface portion 113 and the corner portion 112) is greater than the thickness of the dielectric layer 160 located on the first doped region 130 and the second doped region 140 or the thickness of the dielectric layer 160 on the sidewall of the trench T1. Since the corner portion 112 has a higher dopant concentration than the surface portion 113, the thickness of the dielectric layer 160 located in the corner portion 112 may be greater than the thickness of the dielectric layer 160 located in the surface portion 113.

From another perspective, the dielectric layer 160 may have a vertical portion 160V along the first doped region 130 and the well region 120, and a horizontal portion 160H along the upper surface of the substrate 110, wherein the vertical portion 160V and the horizontal portion 160H meet at a corner portion 160C. In some embodiments, the corner portion 160C is a protruding structure extending outward and downward. That is, the corner portion 160C protrudes outward by a greater distance than the vertical portion 160V, and the corner portion 160C protrudes downward by a greater distance than the horizontal portion 160H. In some embodiments, corner portion 160C is thicker than horizontal portion 160H and vertical portion 160V, and horizontal portion 160H is thicker than vertical portion 160V.

In some embodiments, since the corner portion 160C and the horizontal portion 160H are grown from the modification layer 111, the corner portion 160C and the horizontal portion 160H have a higher dopant concentration than the vertical portion 160V, and the corner portion 160C again has a higher dopant concentration than the horizontal portion 160H. In some embodiments, the dopant concentration of the horizontal portion 160H gradually decreases from both ends to the center.

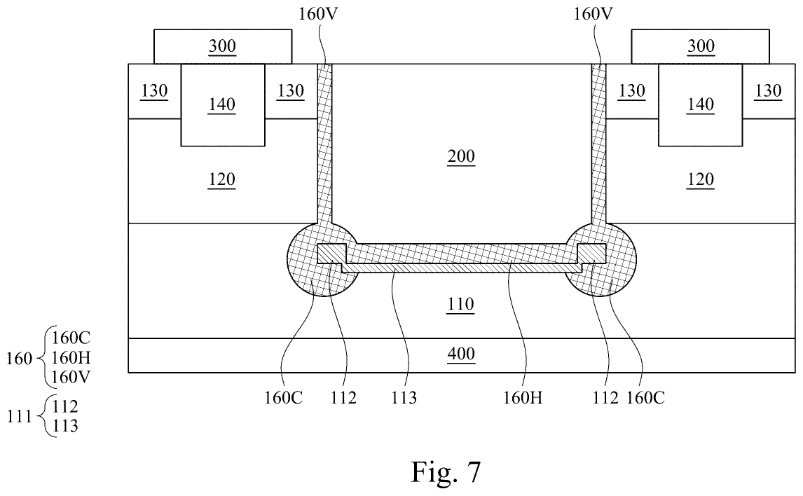

Referring to FIG. 7, a gate structure 200 may be formed in the trench T1, a source electrode 300 may be formed on the first doped region 130 and the second doped region 140, and a drain electrode 400 may be formed under the substrate 110.

In some embodiments, the gate structure 200 may be first deposited in the trench T1, and then a planarization process may be performed to remove excess material on the first doped region 130 and the second doped region 140. The dielectric layer 160 and the gate structure 200 are formed so that the gate structure 200 is leveled with the first doped region 130 and the second doped region 140. The planarized gate structure 200 is coplanar with the first doped region 130 and the second doped region 140, and thus they share the same top surface. That is, the gate structure 200 and the top surfaces of the first doped region 130 and the second doped region 140 may be adjacent to each other.

Next, a second patterned photoresist layer may be formed by deposition to form the source electrode 300. The position of the source electrode 300 is defined by the second patterned photoresist layer. Next, the first patterned photoresist layer is removed. In some embodiments, the source electrode 300 covers an upper surface of the second doped region 140 and a portion of an upper surface of the first doped region 130.

Next, the drain electrode 400 may be formed by vertically flipping the substrate 110 and depositing it on the back side of the substrate 110. After the drain electrode 400 is formed, it can be vertically flipped back to its original position. In some embodiments, the drain electrode 400 covers the lower surface of the substrate 110. The gate structure 200, the source electrode 300 and the drain electrode 400 may be made of a conductive material, such as metal.

Currently in SiC Trench MOSFET, the corner area is often affected by high electric fields due to the phenomenon of electric field concentration. Such concentrated electric field usually occurs at the sharp corners of the gate structure 200, especially at the edge of the structure such as the trench T1. Specifically, these high electric fields at the corners may have a negative impact on the dielectric layer 160, thereby causing problems such as degradation or breakdown of the dielectric layer 160, increased leakage current, reduced device breakdown voltage, or failure of the switching function.

However, the present disclosure proposes an arched oxide layer structure, which improves the problem of the corner oxide layer being broken down by a high electric field under a conventional structure, and increases the oxide layer in the region by implanting ions with a high concentration (such as forming a modified layer 111). The rate increases so that when the gate oxide layer (such as the dielectric layer 160) grows, the thickness of the corners increases, which can more effectively withstand voltage.

Although the present disclosure has been described in considerable detail with reference to certain embodiments thereof, other embodiments are possible. Therefore, the spirit and scope of the appended claims should not be limited to the description of the embodiments contained herein. It will be apparent to those skilled in the art that various modifications and variations can be made to the structure of the present disclosure without departing from the scope or spirit of the disclosure. In view of the foregoing, it is intended that the present disclosure cover modifications and variations of this disclosure provided they fall within the scope of the following claims.

What is claimed is:

1. A method of fabricating a semiconductor device, comprising:
forming a trench in a substrate;
forming a barrier layer on a sidewall of the trench, wherein the trench exposes an upper surface of the substrate;
via the trench, performing an etching back process on the substrate to lower the upper surface of the substrate and exposing a side surface of the substrate;
modifying an oxidation characteristic of the exposed upper surface and the side surface of the substrate;
depositing a dielectric layer on the upper surface and the side surface of the substrate; and
forming a gate structure on the dielectric layer.

2. The method of claim 1, wherein modifying the oxidation characteristic of the exposed upper surface and the side surface of the substrate comprises implanting a doping species into the substrate.

3. The method of claim 2, wherein the doping species is a P-type dopant, nitrogen (N) or argon (Ar).

4. The method of claim 2, wherein the doping species is implanted into the substrate at an inclined angle.

5. The method of claim 1, further comprises removing the barrier layer before depositing the dielectric layer.

6. The method of claim 1, wherein forming the barrier layer comprises:
forming a barrier layer material along the trench; and
removing a portion of the barrier layer material located above the upper surface of the substrate.

7. A semiconductor device, comprising:
a substrate;
a gate dielectric layer located in the substrate and having a horizontal portion along an upper surface of the substrate and a vertical portion along a side wall of the substrate, wherein the horizontal portion and the vertical portion intersect at a corner portion, wherein a doping species concentration of the corner portion is higher than a doping species concentration of the horizontal portion; and
a gate structure located on the gate dielectric layer.

8. The semiconductor device of claim 7, wherein a thickness of the corner portion is greater than a thickness of the horizontal portion and a thickness of the vertical portion.

9. The semiconductor device of claim 8, wherein the thickness of the horizontal portion is greater than the thickness of the vertical portion.

10. The semiconductor device of claim 7, wherein the horizontal portion and the corner portion have a doping species, wherein the doping species is a P-type dopant, nitrogen (N) or argon (Ar).
